(19) United States
(12) Patent Application Publication
(10) Pub. No.: US 2021/0367185 A1
(43) Pub. Date: Nov. 25, 2021

(54) ORGANIC LIGHT-EMITTING DIODE DISPLAY PANEL

(71) Applicant: Shenzhen China Star Optoelectronics Semiconductor Display Technology Co., Ltd., Shenzhen, Guangdong (CN)

(72) Inventor: Xiang XIAO, Shenzhen, Guangdong (CN)

(21) Appl. No.: 16/498,026

(22) PCT Filed: Aug. 13, 2019
(86) PCT No.: PCT/CN2019/100320

§ 371 Date: Sep. 26, 2019

(30) Foreign Application Priority Data
Apr. 29, 2019 (CN) 201910354689.0

(51) Int. Cl. H01L 51/52; H01L 27/32

(52) U.S. Cl. CPC H01L 51/5228; H01L 27/3279; H01L 51/5234

(57) ABSTRACT

An organic light-emitting display panel, including: a display region; a periphery region; a substrate; at least one sub-pixel region disposed in the display region; a cathode, wherein an input end of the cathode extends to the periphery region; an auxiliary cathode; and at least one contact hole. The cathode is electrically connected to the auxiliary cathode by the contact hole. The farther a distance between the contact hole and the input end of the cathode is, the larger a size of the contact hole is. Each sub-pixel region includes at least one contact hole.

### FIELD

The present disclosure relates to a field of display technology and, more particularly, relates to an organic light-emitting diode display panel.

### BACKGROUND

In self-luminescence display panels, especially in top-emitting devices, cathodes are usually an extremely thin metal film for high light transmission. However, the extremely thin metal has a large impedance and causes a voltage (IR) drop, which results in nonuniformity of light emitted from the display panel. Typically, influence of the IR drop is alleviated by adding auxiliary cathode wires in pixels. As shown in FIG. 1, sizes of contact holes of every pixel are the same, which can only reduce a same amount of IR drop. However, different positions of the display panel have different levels of IR drop, nonuniformity problem of the display panels is still desired to be solved. Consequently, it is necessary to provide an organic light-emitting display panel to solve the above problem.

### SUMMARY

A purpose of the present disclosure is to provide an organic light-emitting display panel. The organic light-emitting display panel includes a display region; a periphery region; a substrate; at least one sub-pixel region disposed in the display region; a cathode, wherein an input end of the cathode extends to the periphery region; an auxiliary cathode; and at least one contact hole. The cathode is electrically connected to the auxiliary cathode by the contact hole. Each sub-pixel region corresponds to at least one contact hole. The farther a distance between the contact hole and the input end of the cathode is, the larger a size of the contact hole is. Contact resistance between the auxiliary cathode and the cathode is reduced by larger contact holes, which can reduce more cathode voltage and can make a practical cathode voltage much closer to an input end voltage of the cathode. Therefore, differences between resistances of different positions of the cathode are within the allowable range, which makes differences between IR drops of different positions of the cathode are within the allowable range. As a result, light emitted from the display panel becomes more uniform.

To achieve the above purpose, the present disclosure provides an organic light-emitting display panel, including: a display region; a periphery region; a substrate; at least one sub-pixel region disposed in the display region; a cathode, wherein an input end of the cathode extends to the periphery region; an auxiliary cathode. The auxiliary cathode includes at least one first metal wire disposed to extend along a first direction and at least one second metal wire disposed to extend along a second direction. The first metal wire is disposed every m rows of the sub-pixel region, the second metal wire is disposed every n columns of the sub-pixel region, and both m and n are positive integers. The organic light-emitting display panel further includes at least one contact hole, wherein the cathode is electrically connected to the auxiliary cathode by the contact hole. Each sub-pixel region corresponds to at least one contact hole. The farther a distance between the contact hole and the input end of the cathode is, the larger a size of the contact hole is.

Furthermore, at least one contact hole is defined in the sub-pixel region.

Furthermore, distances between center points of each two contact holes, which are adjacent to each other and correspond to a same first metal wire, are the same.

Furthermore, the contact hole is a circle, an elliptical, or a polygon.

Furthermore, material of wires of the auxiliary cathode is a conductive metal material.

Furthermore, the organic light-emitting display panel further includes a plurality of top-gate organic light-emitting diodes (OLEDs) disposed on each sub-pixel region.

Furthermore, the cathode is a transparent electrode.

An organic light-emitting display panel, including: a display region; a periphery region; a substrate; at least one sub-pixel region disposed in the display region; a cathode, wherein an input end of the cathode extends to the periphery region; an auxiliary cathode; and at least one contact hole. The cathode is electrically connected to the auxiliary cathode by the contact hole; wherein each sub-pixel region corresponds to at least one contact hole. The farther a distance between the contact hole and the input end of the cathode is, the larger a size of the contact hole is.

Furthermore, the auxiliary cathode includes at least one first metal wire disposed to extend along a first direction.

Furthermore, the auxiliary cathode includes at least one second metal wire disposed to extend along a second direction.

Furthermore, the first metal wire is disposed every m rows of the sub-pixel region, the second metal wire is disposed every n columns of the sub-pixel region, and both m and n are positive integers.

Furthermore, at least one contact hole is defined in the sub-pixel region.

Furthermore, distances between center points of each two contact holes, which are adjacent to each other and correspond to a same first metal wire, are the same.

Furthermore, the contact hole is a circle, an elliptical, or a polygon.

Furthermore, material of wires of the auxiliary cathode is a conductive metal material.

Furthermore, the organic light-emitting display panel further includes a plurality of top-gate organic light-emitting diodes (OLEDs) disposed on each sub-pixel region.

Furthermore, the cathode is a transparent electrode.

Regarding the beneficial effects of the present disclosure: different size contact holes are defined in sub-pixel regions in different positions of the display panel, larger size contact holes are defined in a position which has serious IR drop to reduce more IR drop, smaller size contact holes are defined in a position which has slight IR drop. As a result, cathode voltage of the entire display panel is more uniform, and display images can be displayed uniformly.

### DESCRIPTION OF DRAWINGS

The accompanying figures to be used in the description of embodiments of the present disclosure or prior art will be described in brief to more clearly illustrate the technical solutions of the embodiments or the prior art. Apparently, the accompanying figures described below are only part of the embodiments of the present disclosure, from which figures those skilled in the art can derive further figures without making any inventive efforts.

FIG. 1 is a schematic structural diagram of an organic light-emitting display panel according to conventional technology.

FIG. 2 is a schematic structural diagram of an organic light-emitting display panel according to one embodiment of the present disclosure

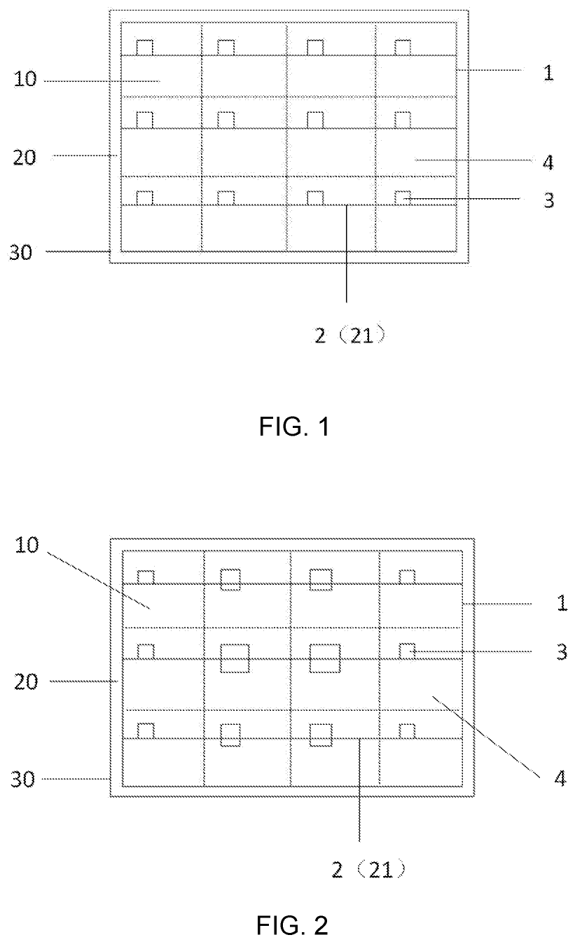

### DETAILED DESCRIPTION

Hereinafter a preferred embodiment of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure. Hereinafter a preferred embodiment of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure.

Terms “first”, “second”, “third”, etc. (if present) in the specification and claims of the present invention and the above figures are used to distinguish similar objects, which are not used to describe a specific order. It should be noted that the objects can be interchanged in an appropriate case. In addition, terms “comprising” and “including” and any variants thereof are intended to cover non-exclusive inclusions.

In the present disclosure, drawings which are discussed below, and various embodiments used to describe the principles of the present disclosure are intended to be illustrative only instead of limiting the scope of the present disclosure. Those skilled in the art will understand that the principles of the present disclosure may be implemented in any suitably arranged system. In the drawings, the implementations are illustrated in detail. Moreover, a terminal according to an exemplary embodiment will be described in detail with reference to the accompanying drawings. In the accompanying drawings, the identical or similar reference numerals constantly denote the identical or similar elements or elements having the identical or similar functions.

Terms used in the description of the present disclosure are only used to describe specific embodiments, but not intended to show the concept of the invention. Unless specified or limited otherwise, it should be noted that expressions used in the singular encompass the plural forms of expression. In the present disclosure, it should be noted, terms such as “including”, “including” and “having” are intended to mean that there is a possibility of the features, numbers, steps, acts, or combinations thereof, and are not intended to exclude one or more possibilities of other features, numbers, steps, actions or combinations thereof. In the accompanying drawings, the identical or similar reference numerals constantly denote the identical or similar elements or elements having the identical or similar functions.

Referring to FIG. 2, the present disclosure provides an organic light-emitting display panel. The organic light-emitting display panel includes a display region 10, a periphery region 20, a substrate 30, and a plurality of organic light-emitting diode (OLED) devices (not shown) on the display region 10 which are disposed on the substrate 30. Each of the OLED devices includes a cathode 1, wherein an input end of the cathode 1 on the display region 10 extends to the periphery region 20; an auxiliary cathode 2, wherein the auxiliary cathode 2 is disposed on the substrate 30; and at least one contact hole 3, wherein the cathode 1 is electrically connected to the auxiliary cathode 2 by the contact hole 3.

Referring to FIG. 2, the organic light-emitting display panel is especially suitable for large size top light-emitting devices. The organic light-emitting display panel of an embodiment of the present disclosure is a top light-emitting display panel. The cathode 1 is a transparent electrode. To obtain high light transmission, the cathode 1 of the organic light-emitting display panel is an extremely thin metal film and has a large impedance. The input end of the cathode 1 extends to the periphery region 20. In the present embodiment, the display region 10 is a rectangle and is surrounded by the periphery region 20. As a result, a practical voltage of the cathode 1 at a center the display region 10 is greater than a voltage of the periphery region 20.

It should be noted, in the top light-emitting display panel, the display region 10 further includes at least one sub-pixel region 4. Each sub-pixel region 4 includes one OLED device. FIG. 2 only shows the cathode 1 of the OLED device, and a specific structure of the OLED device is not shown. Each OLED device of each sub-pixel region 4 further includes an anode, a luminescent layer, and the cathode 1. The anode and the luminescent layer are not shown in the figure.

Material of the cathode 1 can be a transparent conductive material such as indium tin oxide (ITO) and indium doped zinc oxide (IZO).

Referring to FIG. 2, in an embodiment of the present disclosure, the auxiliary cathode 2 includes at least one first metal wire 21 disposed to extend along a first direction. The first metal wire 21 is evenly disposed every m rows of the sub-pixel region 4, and m is a positive integer.

In other embodiments, the auxiliary cathode 2 includes at least one second metal wire (not shown) disposed to extend along a second direction. The second metal wire is evenly disposed every n columns of the sub-pixel region 4, and n is a positive integer.

In other embodiment, the auxiliary cathode 2 includes at least one first metal wire disposed to extend along a first direction and at least one second metal wire (not shown) disposed to extend along a second direction. The first metal wire and the second metal wire are disposed evenly and are disposed to cross each other. The first metal wire is directly connected to the second metal wire.

In the above embodiment, wires of the first metal wire and wires of the second metal wire both extend from the display region 10 to the periphery region 20. In the present disclosure, widths of the first metal wire and the second metal wire are adjusted. Within a reasonable range, the wider the first metal wire and the second metal wire are, the lower the impedance of the auxiliary cathode 2 is.

In an organic light-emitting display panel provided by an embodiment of the present disclosure, the cathode 1 and the auxiliary cathode 2 are disposed on different layers.

In some embodiments of the present disclosure, the auxiliary cathode 2 is disposed between the substrate 30 and the OLED device. Furthermore, the OLED device is formed after the auxiliary cathode 2 is formed, thereby ensuring that the auxiliary cathode 2 will not affect an aperture of the sub-pixel region 4 which corresponds to the OLED device.

In some embodiments of the present disclosure, the organic light-emitting display panel further includes a thin film transistor (not shown) disposed on the substrate 30. The thin film transistor is used for driving the OLED device to realize a display function and improve a resolution. The thin film transistor includes a gate electrode and a source/drain electrode. The OLED device can be a top-gate OLED which disposed on each sub-pixel region. The cathode 1 is a transparent electrode.

In some embodiments, the auxiliary cathode 2 is disposed between the thin film transistor and the OLED device, that is, the auxiliary cathode 2 is formed after the thin film transistor is formed. Then, the anode of the OLED device, the luminescent layer, and the cathode 1 are sequentially formed.

In some embodiments, the auxiliary cathode 2 and the gate electrode of the thin film transistor can be disposed on a same layer.

In some embodiments, the auxiliary cathode 2 and the source/drain electrode can be disposed on a same layer.

Referring to FIG. 2. material of the auxiliary cathode 2 is a conductive metal material such as Mo, Al, Cr, Au, Ag, and a combination thereof, which will not be limited here.

Referring to FIG. 2, in an embodiment of the present disclosure, the contact hole 3 is disposed on a layer between the cathode 1 and the auxiliary cathode 2. Each sub-pixel region 4 corresponds to at least one contact hole 3. The contact hole 3 is evenly defined in the display region 10.

Referring to FIG. 2, In the organic light-emitting display panel provided by an embodiment of the present disclosure, distances between center points of each two contact holes 3, which are adjacent to each other and correspond to a same first metal wire 21, are the same. The farther a distance between the contact hole 3 and the input end of the cathode 1 is, the larger a size of the contact hole 3 is. That is, in the present embodiment, the input end of the cathode 1 of the display region 10 extends to the periphery region 20. The display region 10 is a rectangle, In the display region 10, a contact hole 3 corresponding to a center of the display region 10 is larger, whereas a contact 3 corresponding to a periphery of the display region 10 is smaller.

In the present embodiment, the contact hole 3 is a rectangle with different side lengths. In other embodiments, the contact hole 3 can be a circle, an elliptical, a polygon, or other shapes.

Referring to FIG. 2, the cathode 1 and the auxiliary cathode 2 are electrically connected to each other by the contact hole 3 which corresponds to the cathode 1, thereby realizing a parallel connection of the cathode 1 with the auxiliary cathode 2. In other words, the cathode 1 is parallel connected to a resistor, thereby reducing an impedance of the cathode 1. The larger a size of the contact hole 3 is, the larger a contact area between the cathode 1 and the auxiliary cathode 2 is. Therefore, contact resistance between the cathode 1 and the auxiliary cathode 2 is reduced, thereby reducing more cathode voltage and making a practical voltage of the cathode 1 much closer to an input end voltage. Therefore, differences between resistances of different positions of the cathode 1 are within the allowable range, which makes differences between IR drops of different positions of the cathode are within the allowable range. As a result, light emitted from the display panel becomes more uniform.

The above are merely preferred embodiments of the present invention. It is understood that many changes and modifications to the described embodiment can be carried out without departing from the scope and the spirit of the disclosure that is intended to be limited only by the appended claims.

What is claimed is:

1. An organic light-emitting display panel, comprising:
a display region;
a periphery region;
a substrate;
at least one sub-pixel region disposed in the display region;
a cathode, wherein an input end of the cathode extends to the periphery region;
an auxiliary cathode, wherein the auxiliary cathode comprises at least one first metal wire disposed to extend along a first direction and at least one second metal wire disposed to extend along a second direction; and
wherein the first metal wire is disposed every m rows of the sub-pixel region, the second metal wire is disposed every n columns of the sub-pixel region, and both m and n are positive integers; and
at least one contact hole, wherein the cathode is electrically connected to the auxiliary cathode by the contact hole;
wherein each sub-pixel region corresponds to at least one contact hole; and
wherein the farther a distance between the contact hole and the input end of the cathode is, the larger a size of the contact hole is.

2. The organic light-emitting display panel of claim 1, wherein at least one contact hole is defined in the sub-pixel region.

3. The organic light-emitting display panel of claim 1, wherein distances between center points of each two contact holes, which are adjacent to each other and correspond to a same first metal wire, are the same.

4. The organic light-emitting display panel of claim 1, wherein the contact hole is a circle, an elliptical, or a polygon.

5. The organic light-emitting display panel of claim 1, wherein material of wires of the auxiliary cathode is a conductive metal material.

6. The organic light-emitting display panel of claim 1, wherein the organic light-emitting display panel further comprises a plurality of top-gate organic light-emitting diodes (OLEDs) disposed on each sub-pixel region.

7. The organic light-emitting display panel of claim 6, wherein the cathode is a transparent electrode.

8. An organic light-emitting display panel, comprising:
a display region;
a periphery region;
a substrate;
at least one sub-pixel region disposed in the display region;
a cathode, wherein an input end of the cathode extends to the periphery region;
an auxiliary cathode; and
at least one contact hole, wherein the cathode is electrically connected to the auxiliary cathode by the contact hole;
wherein each sub-pixel region corresponds to at least one contact hole; and
wherein the farther a distance between the contact hole and the input end of the cathode is, the larger a size of the contact hole is.

9. The organic light-emitting display panel of claim 8, wherein the auxiliary cathode comprises at least one first metal wire disposed to extend along a first direction.

10. The organic light-emitting display panel of claim 8, wherein the auxiliary cathode comprises at least one second metal wire disposed to extend along a second direction.

11. The organic light-emitting display panel of claim 8, wherein the first metal wire is disposed every m rows of the sub-pixel region, the second metal wire is disposed every n columns of the sub-pixel region, and both m and n are positive integers.

12. The organic light-emitting display panel of claim 8, wherein at least one contact hole is defined in the sub-pixel region.

13. The organic light-emitting display panel of claim 8, wherein distances between center points of each two contact holes, which are adjacent to each other and correspond to a same first metal wire, are the same.

14. The organic light-emitting display panel of claim 8, wherein the contact hole is a circle, an elliptical, or a polygon.

15. The organic light-emitting display panel of claim 8, wherein material of wires of the auxiliary cathode is a conductive metal material.

16. The organic light-emitting display panel of claim 8, wherein the organic light-emitting display panel further comprises a plurality of top-gate organic light-emitting diodes (OLEDs) disposed on each sub-pixel region.

17. The organic light-emitting display panel of claim 16, wherein the cathode is a transparent electrode.
